(19) United States
(12) Patent Application Publication
(10) Pub. No.: US 2022/0155102 A1
(43) Pub. Date: May 19, 2022

(54) CONTACTLESS MAGNETIC SENSING SYSTEM

(71) Applicant: Haechitech Corporation, Cheongju-si (KR)

(72) Inventor: Eun Joong KIM, Seoul (KR)

(73) Assignee: Haechitech Corporation, Cheongju-si (KR)

(21) Appl. No.: 17/522,432

(22) Filed: Nov. 9, 2021

(30) Foreign Application Priority Data
Nov. 18, 2020 (KR) 10-2020-0154206

(51) Int. Cl. G01D 5/14; G01R 33/00

(52) U.S. Cl. CPC G01D 5/145; G01R 33/0029; G01R 33/0047

(57) ABSTRACT

Disclosed is a contactless magnetic sensing system. Proposed is a sensing system in which multiple magnetic sensors are disposed at the center of a rotating magnet and rotation angles of the magnetic sensors disposed around a center point at intervals of an angle of 90 degrees can be extracted.

### BACKGROUND

### 1. Technical Field

The present disclosure relates to a contactless magnetic sensing system, and more particularly, to magnetic sensors capable of detecting a motion in a three-dimensional (3-D) space, and a system including the magnetic sensors.

### 2. Related Art

In a comparison of performance between mobile devices, a comparison of camera functions, the smoothness of an operation attributable to the installation of various apps, the maximization of storage performance, etc. recently become gradually more important than the superiority and inferiority of a communication function. Furthermore, with the development of the semiconductor technology, physiological information of the human body obtained by several sensors mounted on a mobile device can be processed within the mobile device. A technology is further variously applied, which is intended to obtain information on a motion of a mobile device by using a 3-D sensor or a three-axis sensor and to further increase the utilization of the mobile device by incorporating the information into the mobile device.

Hereinafter, the background technology of the present disclosure is described.

FIG. 1 illustrates a rotating magnet having a round shape and capable of rotating around a rotation axis and a 3-D coordinate system. It is assumed that the N pole and the S pole of the rotating magnet are divided at the center of a circle, for convenience sake, because the N pole and the S pole cannot be separated. It is assumed that a virtual rotation axis is placed at the center of the rotating magnet in order to represent the rotation of the rotating magnet. As everyone knows from common sense, a magnetic line of force indicative of a magnetic field starts from the N pole and reaches the S pole. FIG. 2 illustrates the directions of such magnetic lines of force as lines to which arrows are added.

When the rotating magnet having the rotation axis placed at the origin point of the 3-D coordinate system is viewed from the top, that is, when an X-Y plane is viewed from the top, the rotating magnet seems a circle as in FIG. 3. When rotating around an axis placed at the origin point, the rotating magnet has the shape of rotating circle. Assuming that the N pole is placed on the upper side and the S pole is placed on the lower side right before the rotation starts, an angle formed by the N pole and the S pole is assumed to be 0. When the rotating magnet rotates, the direction of the magnetic field also rotates. In the coordinate system of FIG. 3, if the intensity of a magnetic field at the origin point is measured, a Y-axis component of the magnetic field becomes a maximum and an X-axis component of the magnetic field becomes a minimum when a rotation angle is 0 degree. The Y-axis component of the magnetic field becomes a minimum and the X-axis component of the magnetic field becomes a maximum when the rotation angle is 90 degrees. A Z-axis component of the magnetic field is constant because the rotation is performed on the X-Y plane.

Accordingly, when rotation is performed around the origin point from 0 degree to 360 degrees and performed once, in a change in the magnetic field in each axial direction of magnetism measured at the origin point, the X-axis component is represented as a sine waveform, the Y-axis component is represented as a cosine waveform, and the Z-axis component is constant as illustrated in FIG. 4. In FIG. 4, a horizontal axis indicates a rotation angle, and a vertical axis indicates the magnitude of a magnetic field. When the rotating magnet and sensors for measuring magnetic fields are placed at the origin point, the Z-axis component of the magnetic field is 0, which is illustrated as a straight line in FIG. 4. However, since the rotating magnet cannot practically occupy the same space as the sensors, the rotating magnet is slightly spaced apart from the origin point at which the sensors are present. In this case, the Z-axis component of the magnetic field is weakly detected, but becomes a constant regardless of rotation, which is illustrated as a dotted line in FIG. 4. The magnetic field may be detected by a hall sensor using a hall effect, etc.

An angle formed by the rotating magnet on the X-Y plane may be indicated as the X-axis component and Y-axis component of magnetism. In an angular diagram illustrated in FIG. 5, when rotation angles are 0 degree, 90 degrees, 180 degrees, and 270 degrees, respectively, corresponding components may be represented as [0,1], [1,0], [0,−1], and [−1,0], respectively. In this case, the values of 0, 1, and −1 within “[ ]” indicate a minimum value, a positive maximum value, and a negative maximum value, respectively. Values within “[ ]” at other given angles are within the range from −1 to 1. That is, the values within “[ ]” correspond to the outputs of the sensors. An angle of the rotating magnet can be accurately known from the outputs. More accurately, an angle of the rotating magnet can be known by applying arctangent to a value within “[ ].” If the rotation axis of the rotating magnet is precisely coincident with the center point of the X-sensor and the Y-sensor, a shape of the angular diagram of FIG. 5 becomes a complete circular shape having a center point as the origin point. Since the value of the Z-axis component of a magnetic field is 0, a shape of each of a Z-Y diagram and a Z-X diagram becomes a straight line as illustrated in FIG. 5, and becomes a dotted line when the value thereof is small, but is constant.

In this case, however, there is a disadvantage in that the rotating magnet cannot be additionally disposed at the origin point accurately because the sensors need to be disposed at the origin point and the sensors occupy a space.

### PRIOR ART DOCUMENT

### Patent Document

Patent Document: U.S. Pat. No. 10,551,222 B2 (Feb. 4, 2020)

### SUMMARY

Various embodiments are directed to providing a system capable of detecting a magnetic field in a three-dimensional (3-D) space by using only magnetic sensors responsible for one axis in detecting the magnetic field in the 3-D space.

Also, various embodiments are directed to providing a system having increased space utilization by disposing a rotating magnet at the center of a plane where magnetic sensors are present and disposing the magnetic sensors at a given distance from the center point.

Also, various embodiments are directed to providing a system capable of detecting a rotation angle of a rotating magnet by using only two magnetic sensors for detecting a magnetic field in only one axial direction in detecting a magnetic field in a 3-D space.

In an embodiment, a contactless magnetic sensing system may include multiple magnetic sensors each configured to measure a magnetic field in one axial direction in a three-dimensional (3-D) space, a rotating magnet having a rotation axis placed at an intersection or center point of a diagonal line formed by the magnetic sensors, and a substrate on which the magnetic sensors are disposed.

In an embodiment, a contactless magnetic sensing system may include a first sensor configured to measure a magnetic field in one axial direction in a three-dimensional (3-D) space, a second sensor disposed around a center point at an interval of 90 degrees with respect to the first sensor, a rotating magnet having a rotation axis placed at the center point, and a substrate on which the magnetic sensors are disposed.

According to an embodiment of the present disclosure, the contactless magnetic sensing system can reduce a cost for parts, and can improve the utilization of the space where the rotation magnet is disposed, because magnetic sensors can be disposed away from a center point.

### BRIEF DESCRIPTION OF THE DRAWINGS

FIG. 1 illustrates a rotating magnet and a coordinate system thereof.

FIG. 2 illustrates directions of magnetic fields when a rotating magnet is viewed from the side.

FIG. 3 illustrates the rotating magnet when viewed from the top and a coordinate system thereof.

FIG. 4 illustrates 3-D axis components of magnetic fields by the rotating magnet.

FIG. 5 illustrates angular diagrams.

FIG. 6 illustrates the arrangement of one type of magnetic sensors.

FIG. 7 illustrates the arrangement of one type of magnetic sensors and a rotating magnet.

FIG. 8 illustrates changes in magnetic fields according to the rotation of the rotating magnet detected by one type of magnetic sensors.

FIG. 9 is a plane diagram in which the number of one type of magnetic sensors is minimized.

FIG. 10 is a perspective view in which the number of one type of magnetic sensors is minimized.

FIG. 11 illustrates angular diagrams when the number of one type of magnetic sensors is minimized.

FIG. 12 illustrates a contactless magnetic sensing system.

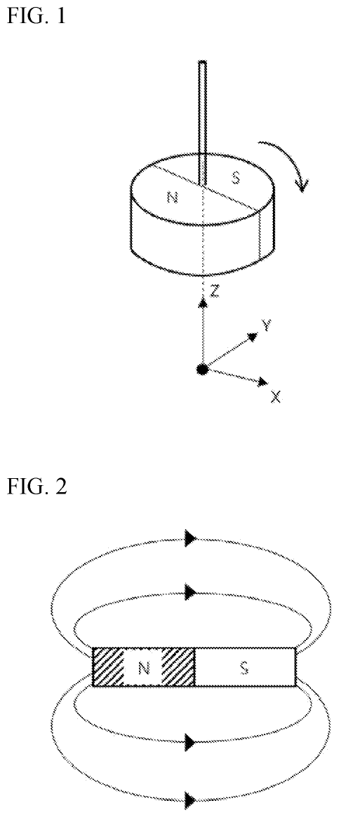

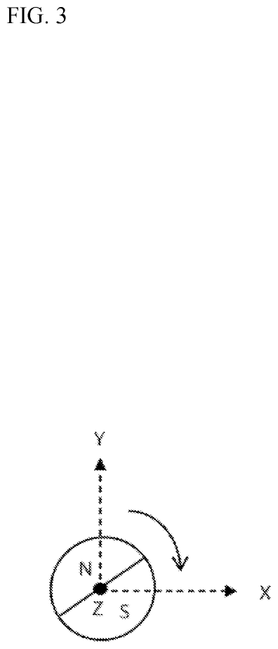

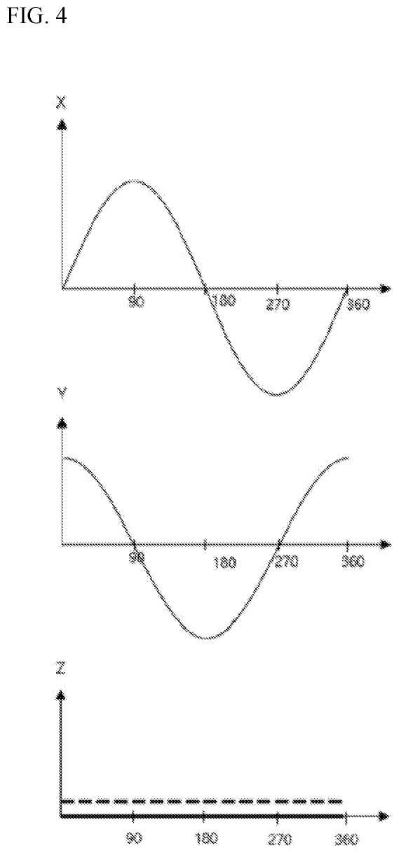

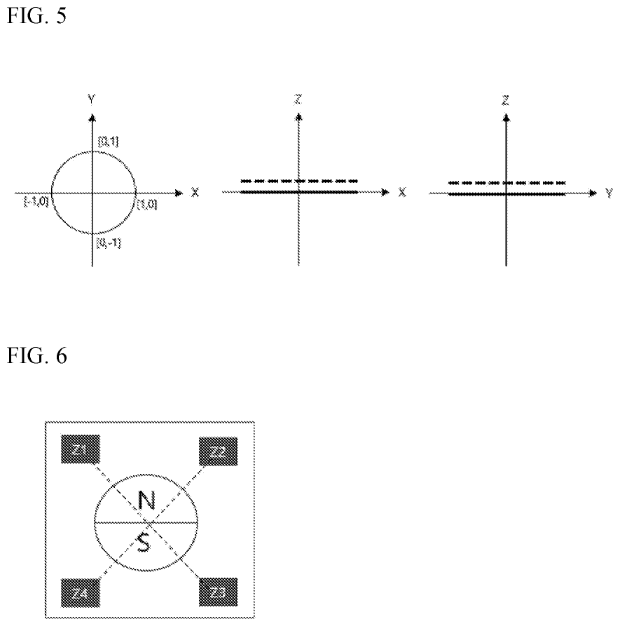

### DETAILED DESCRIPTION

Hereinafter, embodiments of the present disclosure are described in detail with reference to the accompanying drawings in order for a person having ordinary knowledge in the art to which the present disclosure pertains to easily carry out the present disclosure. In the drawings, the same reference numeral is used to refer to the same member throughout the specification.

In describing the present disclosure, a detailed description of a related known technology will be omitted if it is deemed to make the subject matter of the present disclosure unnecessarily vague.

Terms, such as a “first” and a “second”, may be used to describe various elements, but the elements are not restricted by the terms. The terms are used to only distinguish one element from the other element.

In an embodiment of the present disclosure, there are disclosed a contactless rotating magnet in which the axis of a rotating magnet is disposed away from the center of a magnetic sensor and a system thereof.

In the entire specification of the present disclosure, a term described as a “substrate” is used to collectively refer to a semiconductor integrated circuit or a printed circuit board on which a variety of types of magnetic sensors have been mounted or formed, a printed circuit board including a semiconductor integrated circuit, and various modules which may be mounted as parts on a completed electronic product, but may be used to limitedly describe an element including a plane in which magnetic sensors are disposed for convenience of description according to circumstances.

Furthermore, in the entire specification of the present disclosure, the meaning of an “origin point” or a “center point” refers to a point at which the rotation axis of a rotation sensor and a sensing plane in which magnetic sensors are placed or disposed are orthogonal to each other.

Furthermore, in the present disclosure, the rotation axis of a rotating magnet and the extension line of the rotation axis may be a virtual axis and a virtual line for describing rotation, respectively.

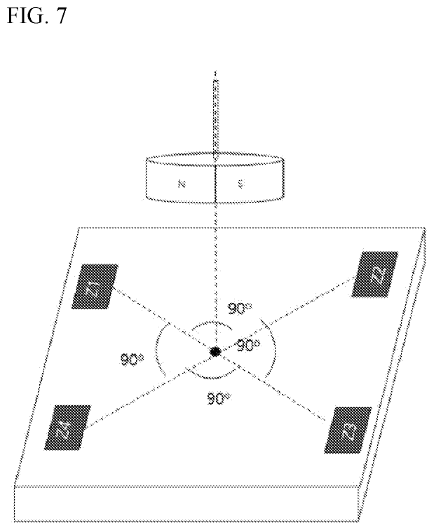

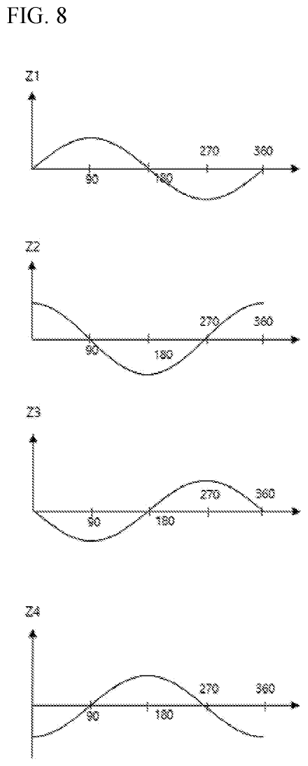

According to an embodiment of the present disclosure, magnetic fields in a three-axis direction may be detected using four Z-axis magnetic sensors without the help of an X-axis magnetic sensor and a Y-axis magnetic sensor. As illustrated in FIGS. 6 and 7, when Z-axis magnetic sensors Z1, Z2, Z3, and Z4 are disposed at four corner portions, respectively, and a rotating magnet is placed at a central part of the Z-axis magnetic sensors, magnitude of magnetism in a Z-axis direction may be detected. As illustrated in FIG. 8, the detected magnitudes of the Z-axis magnetic sensors have a phase difference of 90 degrees for each magnetic sensor. Such a phase difference is caused because the four Z-axis magnetic sensors are arranged by a difference of 90 degrees on the basis of the center point of a sensing plane. In this case, the sensing plane may mean a plane in which the Z-axis magnetic sensors are disposed or to which the Z-axis magnetic sensors are attached.

A more important thing is as follows. As may be seen from FIG. 8, a value detected by the Z1-axis magnetic sensor among the four Z-axis magnetic sensors has smaller amplitude than values of the X-axis magnetic sensor, but has the same phase as the values of the X-axis magnetic sensor. Likewise, a value detected by the Z3-axis magnetic sensor has only smaller amplitude than values of the Y-axis magnetic sensor, but has the same phase as the values of the Y-axis magnetic sensor. Values detected by the remaining Z2-axis magnetic sensors and Z4-axis magnetic sensor have the same amplitude as the values detected by the Z1-axis and Z3-axis magnetic sensors, respectively, but each have only a phase difference of 90 degrees compared to each of the values detected by the Z1-axis and Z3-axis magnetic sensors. Accordingly, for example, each of values of the Z1-axis to Z3-axis magnetic sensors may have phase information, which is identical or similar to a value when the X-axis magnetic sensor is disposed at the center point of the sensing plane although the X-axis magnetic sensor is not present. Each of values of the Z2-axis to Z4-axis magnetic sensors may have phase information, which is identical or similar to a value when the Y-axis magnetic sensor is disposed at the center point of the sensing plane and the output of the Y-axis magnetic sensor although the X-axis magnetic sensor is not present.

In this case, the utilization of a space around the origin point is increased because a motion in a 3-D space can be detected by using only the four Z-axis magnetic sensors without a sensor disposed at the origin point, but the number of magnetic sensors needs to be four. Another embodiment of the present disclosure discloses a system capable of detecting a magnetic field in a 3-D space although the number of magnetic sensors is further reduced. In such an embodiment, magnetic fields in a three-axis direction can be detected in a more cost effective way due to another advantage of reducing costs for parts. This embodiment discloses a contactless rotating magnet in which the rotation axis of a rotating magnet is coincident with the center point of a plane in which only two Z-axis magnetic sensors are disposed or the rotation axis of the rotating magnet is disposed at least close to the center point of the plane, and a system including the contactless rotating magnet.

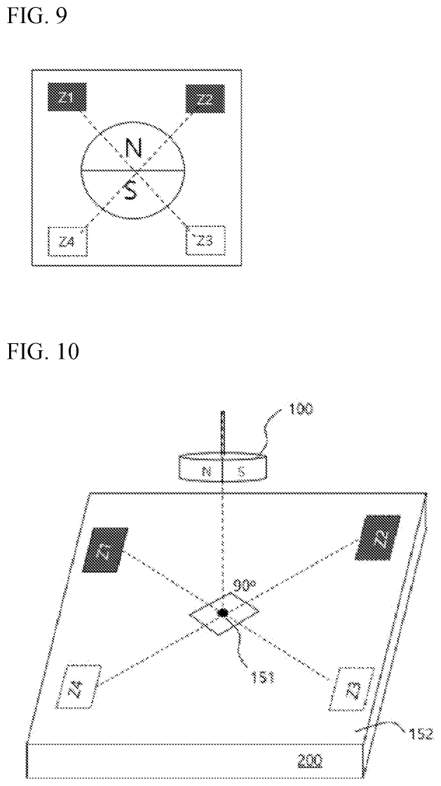

Another embodiment of the present disclosure is described with reference to a plane diagram of FIG. 9 and a perspective view of FIG. 10. The present embodiment has other advantages in that the utilization of a space around the origin point is increased and a cost for parts is reduced because the number of magnetic sensors is further reduced. Such advantages become stronger points when the present disclosure is applied to a mobile device.

A rotating magnet 100 is disposed over a center point 151 of a sensing plane 152 in which magnetic sensors responsible for one axis among magnetic sensors for detecting a magnetic field in a 3-D space, in this case, magnetic sensors indicated as Z-axis magnetic sensors for convenience sake are disposed or over an extension line of the center point. The perspective view of FIG. 10 illustrates that the rotation axis of the rotating magnet 100 has been isolated from the center point 151 in a perpendicular direction, that is, a Z-axis direction, for convenience of description, but the rotation axis comes into contact with the center point 151 or is disposed very close to the center point 151.

The sensing plane 152 means a plane on which magnetic sensors are disposed or mounted, and may practically mean some surfaces of a semiconductor substrate, a printed circuit board, etc.

The center point 151 means an intersection occurring when Z-axis magnetic sensors Z1 and Z2 of the present disclosure are diagonally connected to virtual Z-axis magnetic sensors Z3 and Z4, respectively. In general, the center point 151 is present on the plane 152 of a substrate 200. The center point 151 may be a virtual point according to circumstances.

In the embodiment of the present disclosure illustrated in FIGS. 9 and 10, only the two Z-axis magnetic sensors Z1 and Z2 are present, and are disposed to maintain an angle of 90 degrees when viewed from the center point 151. The remaining two Z-axis magnetic sensors Z3 and Z4 indicated as dotted lines are merely virtual sensors drawn on a diagonal line, for convenience of description, but are not actually present.

When the center point 151 or the N pole of the rotating magnet 100 disposed very close to the center point is accurately directed toward the Z1-axis magnetic sensor and the S pole of the rotating magnet 100 is disposed on a side opposite to the Z1-axis magnetic sensor, magnitude of a magnetic field detected by the Z1-axis magnetic sensor becomes 0 and magnitude of a magnetic field detected by the Z2-axis magnetic sensor becomes a maximum.

When the rotating magnet 100 clockwise rotates by 90 degrees, such that the N pole of the rotating magnet 100 is accurately directed toward the Z2-axis magnetic sensor, and the S pole of the rotating magnet 100 is disposed on a side opposite to the Z2-axis magnetic sensor, magnitude of a magnetic field detected by the Z2-axis magnetic sensor becomes a maximum and magnitude of a magnetic field detected by the Z1-axis magnetic sensor becomes 0.

When the rotating magnet 100 clockwise rotates by 180 degrees, such that the S pole of the rotating magnet 100 is accurately directed toward the Z1-axis magnetic sensor, and the N pole of the rotating magnet 100 is disposed on a side opposite to the Z1-axis magnetic sensor, magnitude of a magnetic field detected by the Z1-axis magnetic sensor becomes 0, and magnitude of a magnetic field detected by the Z2-axis magnetic sensor becomes a minimum, that is, a negative maximum.

When the rotating magnet 100 clockwise rotates by 270 degrees, such that the S pole of the rotating magnet 100 is accurately directed toward the Z2-axis magnetic sensor, and the N pole of the rotating magnet 100 is disposed on a side opposite to the Z2-axis magnetic sensor, magnitude of a magnetic field detected by the Z1-axis magnetic sensor becomes a minimum, that is, a negative maximum, and magnitude of a magnetic field detected by the Z2-axis magnetic sensor becomes 0.

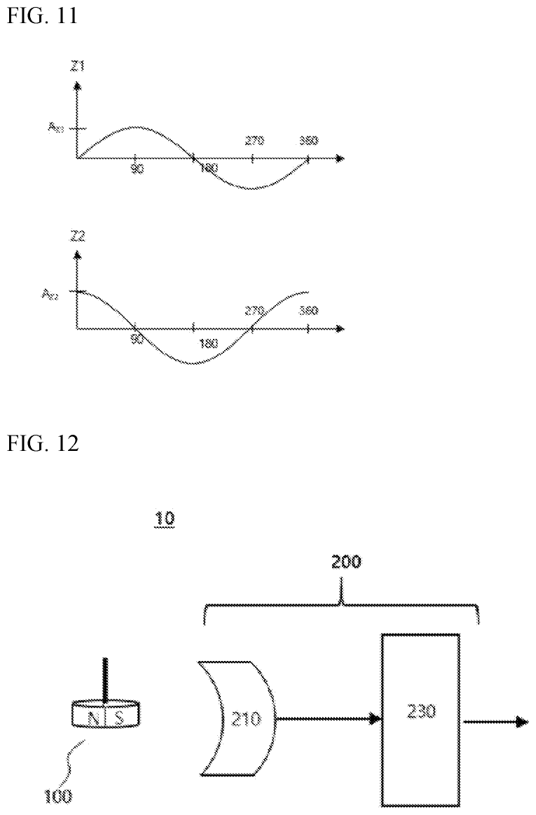

If magnitude of magnetic fields detected by two magnetic sensors, that is, a first sensor and a second sensor indicated as Z1 and Z2 is indicated based on a rotation angle of the rotating magnet 100, as illustrated in FIG. 11, the magnitude of the magnetic field detected by the first sensor (i.e., the Z1-axis magnetic sensor) is represented as a sine waveform, and the magnitude of the magnetic field detected by the second sensor (i.e., the Z2-axis magnetic sensor) is represented as a cosine waveform. Accordingly, the magnitude of the magnetic fields detected by the two magnetic sensors is the same, and phases thereof have a difference of 90 degrees. If distances between the two magnetic sensors and the center point 151 are the same and the two magnetic sensors and the center point 151 are disposed at an angle of accurately 90 degrees, magnetic fields detected by the two magnetic sensors also have the same amplitude A_{Z1} and A_{Z2}.

If the intensities of magnetic fields detected by the two magnetic sensors are small, the magnetic fields may be artificially amplified and properly used. For example, if information of a magnetic field detected by the Z1-axis magnetic sensor is processed by changing a sign of the information, information of an opposite phase can be obtained, which has the same amplitude as that of the Z1-axis magnetic sensor, but has a phase difference of 180 degrees from that of the Z1-axis magnetic sensor. This may be considered as a negative sine waveform. Likewise, if information of a magnetic field detected by the Z2-axis magnetic sensor is processed by changing a sign of the information, information of an opposite phase can be obtained, which has the same amplitude as that of the Z2-axis magnetic sensor, but has a phase difference of 180 degrees from that of the Z2-axis magnetic sensor. This may be considered as a negative cosine waveform.

Furthermore, information of a magnetic field converted into an electric signal by a magnetic sensor may be converted into a digital signal, may be filtered, may be stored or may be used for other calculation, if necessary. The aforementioned several operations may be processed by other elements that receive the output of each magnetic sensor, for example, an amplifier, a signal processor, a signal converter, a memory device, and a filter. Such elements may be included in a control calculation unit 230 constituting a contactless sensing system 10 as illustrated in FIG. 12. In FIG. 12, magnetic sensors are indicated as reference numeral “210”, for convenience sake. The magnetic sensors 210 and the control calculation unit 230 may be formed in one substrate and may be divided and formed in several substrates. In some cases, several functions of the magnetic sensors 210 and the control calculation unit 230 may be divided into one or multiple modules. For this reason, in FIG. 12, the magnetic sensors 210 and the control calculation unit 230 are indicated as reference numeral “200” and are described as the substrate 200.

As described above, according to a core idea of an embodiment of the present disclosure or the present disclosure, a space can be effectively used because magnetic sensors do not need to be disposed at the origin point of a substrate.

According to another embodiment of the present disclosure, costs for parts can be reduced because a magnetic field in a 3-D space can be detected by minimizing the number of magnetic sensors, and a space occupied by magnetic sensors can be further saved when the present disclosure is applied to a mobile device.

The present disclosure has been described based on the embodiments illustrated in the accompanying drawings, but the embodiments are merely illustrative. A person having ordinary knowledge in the art will understand that various modifications and other equivalent embodiments are possible from the embodiments. Accordingly, the true technical range of protection of the present disclosure should be defined by the technical spirit of the appended claims.

### DESCRIPTION OF REFERENCE NUMERALS

| | |
|---|---|
| 10: contactless magnetic sensing system | |
| 100: rotating magnet | 151: origin point |
| 152: sensing plane | 200: substrate |
| 210: magnetic sensors | 230: control calculation unit |

1. A contactless magnetic sensing system comprising:
multiple magnetic sensors each configured to measure a magnetic field in one axial direction in a three-dimensional (3-D) space;
a rotating magnet having a rotation axis placed at an intersection or center point of a diagonal line formed by the magnetic sensors; and
a substrate on which the magnetic sensors are disposed.

2. The contactless magnetic sensing system of claim 1, wherein the substrate is an integrated circuit.

3. The contactless magnetic sensing system of claim 1, wherein the substrate comprises one or more electronic parts and a connection line connecting the one or more electronic parts.

4. The contactless magnetic sensing system of claim 1, wherein the rotation axis of the rotating magnet is placed at an extension line of the intersection and an extension line of the center point not the intersection and the center point.

5. The contactless magnetic sensing system of claim 1, wherein the magnetic sensors are arranged with a difference of an angle of 90 degrees around the intersection of the diagonal line or the center point.

6. The contactless magnetic sensing system of claim 1, wherein lengths of the diagonal lines formed by the magnetic sensors are identical.

7. The contactless magnetic sensing system of claim 1, wherein the magnetic sensors convert, into an electric signal, data of a magnetic field generated by the rotating magnet.

8. The contactless magnetic sensing system of claim 1, wherein the rotation axis is a virtual structure for indicating a rotation of the rotating magnet.

9. The contactless magnetic sensing system of claim 1, wherein the substrate comprises a control calculation unit for calculating a change in magnetic fields detected by the magnetic sensors.

10. A contactless magnetic sensing system comprising:
a first sensor configured to measure a magnetic field in one axial direction in a three-dimensional (3-D) space;
a second sensor disposed around a center point at an interval of 90 degrees with respect to the first sensor;
a rotating magnet having a rotation axis placed at the center point; and
a substrate on which the sensors are disposed.

11. The contactless magnetic sensing system of claim 10, wherein the substrate is an integrated circuit.

12. The contactless magnetic sensing system of claim 10, wherein the substrate comprises one or more electronic parts and a connection line connecting the one or more electronic parts.

13. The contactless magnetic sensing system of claim 10, wherein the rotation axis of the rotating magnet is placed at an extension line of the center point instead of the center point.

14. The contactless magnetic sensing system of claim 10, wherein the magnetic sensors have an identical distance from the center point.

15. The contactless magnetic sensing system of claim 10, wherein the sensors convert, into an electric signal, data of a magnetic field generated by the rotating magnet.

16. The contactless magnetic sensing system of claim 10, wherein the rotation axis is a virtual structure for indicating a rotation of the rotating magnet.

17. The contactless magnetic sensing system of claim 10, wherein the substrate comprises a control calculation unit for calculating a change in magnetic fields detected by the sensors.

18. The contactless magnetic sensing system of claim 17, wherein the control calculation unit performs at least one function among operations of amplifying, filtering, converting, calculating and storing a signal.

19. The contactless magnetic sensing system of claim 1, wherein the sensors are disposed or mounted on an identical plane.

20. The contactless magnetic sensing system of claim 10, wherein the sensors are disposed or mounted on an identical plane.
